(19) United States
(12) Patent Application Publication
(10) Pub. No.: US 2017/0244423 A1
(43) Pub. Date: Aug. 24, 2017

(54) Dynamic Range Extension of Analog-to-Digital Converters

(71) Applicant: JOHN KEENAN, SAINT PAUL, MN (US)

(72) Inventor: JOHN KEENAN, SAINT PAUL, MN (US)

(21) Appl. No.: 15/438,730

(22) Filed: Feb. 21, 2017

Related U.S. Application Data
(60) Provisional application No. 62/297,191, filed on Feb. 19, 2016.

(51) Int. Cl. H03M 1/06; H03M 1/12

(52) U.S. Cl. CPC H03M 1/0617; H03M 1/1245

(57) ABSTRACT

A method and system for extending the dynamic range of non-discontinuous analog data.

### PRIORITY

This Application claims the benefit of U.S. Provisional Application No. 62/297,191, entitled “Dynamic Range Extension of Analog-to-digital Converters” filed Feb. 19, 2016 which is hereby incorporated by reference.

### BACKGROUND

Many digital devices, such as analog-to-digital converters (ADCs), digital signal processors, and scientific instruments have bit depth limits. This allows for reduced computational demands and improved device performance, but results in limiting the size of functions or signals devices can represent. For example, limited bit depths are problematic in ADCs used for audio recording because overflow of the audio signal results in sound distortion. Attempts to solve this problem have included increasing the sample rate or utilizing interleaved or stacked ADCs, but these solutions come with increased cost, labor, and space requirements.

A method that extends the dynamic range of devices with limited bit depth by recovering wrapped signals solves the issue described above. Such method and related opportunities are included in this disclosure.

### SUMMARY

In one embodiment, the present invention provides a method of extending the dynamic range of an analog-to-digital conversion while preserving the overall quality of the signal. The process of the present invention uses an algorithm to locate signal wrapping and restore the waveform, allowing for extended dynamic range and/or increased resolution.

### BRIEF DESCRIPTION OF THE DRAWINGS

This invention will be more readily understood from the following detailed description taken m conjunction with the accompanying drawings, in which:

FIG. 1 illustrates a flow diagram of the process of extending a dynamic range of an Analog-to-Digital Converter according to the present invention.

FIG. 2 illustrates a process flow step of an embodiment of the present invention showing the steps to extend the dynamic range of analog to digital converter.

FIGS. 3-6 illustrate graphical displays of a recording with distortion and matching displays without said distortion.

### BRIEF DESCRIPTION OF THE INVENTION

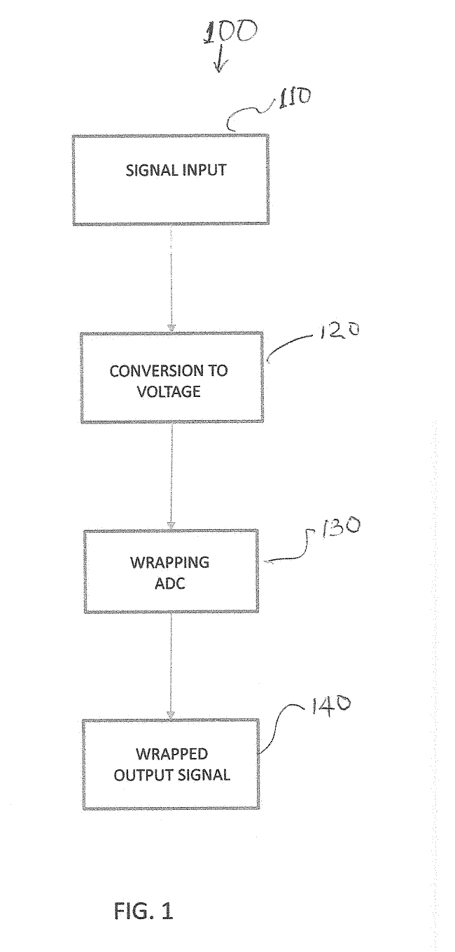

Referring to FIG. 1, the process steps 100 indicate an input step 110 wherein a signal or input is received and converted to voltage 120 using an appropriate process as is known in the art. An analog to digital converter converts the signal front analog to digital while wrapping the digital signal 130. Output of a wrapped digital signal 140 is widely considered undesirable when compared to saturation, which causes less distortion. However, the invention described herein uses wrapped signals to achieve a greater dynamic range than is entirely available with saturation.

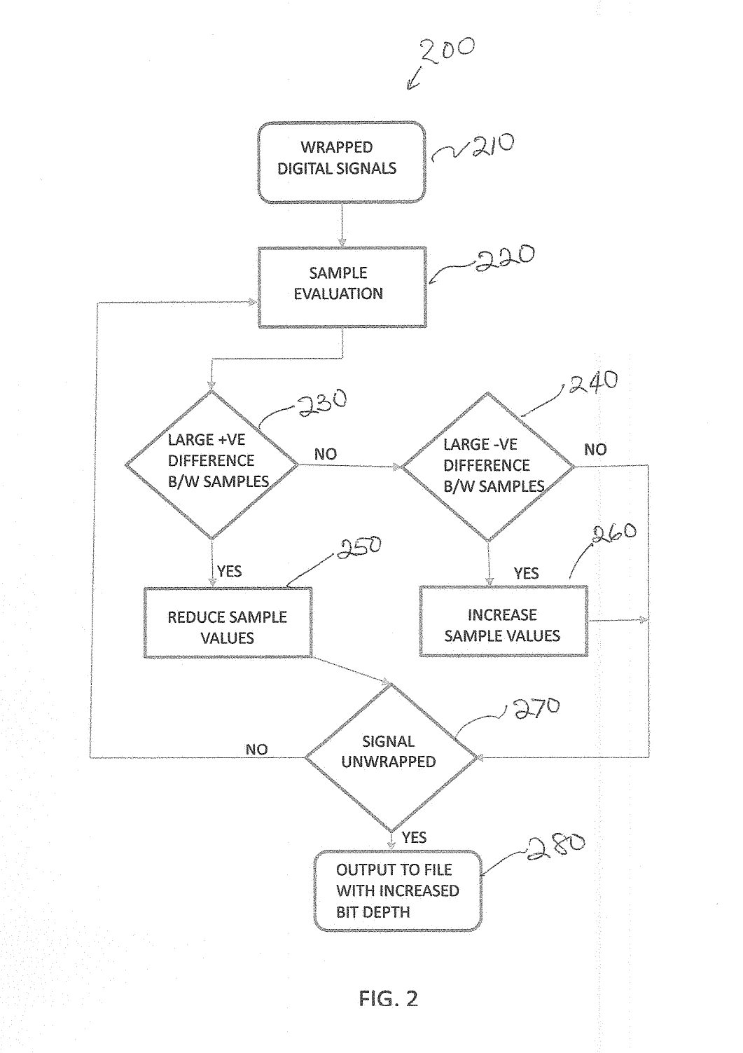

FIG. 2 admits the wrapped digital signal 210 for the process of establishing the quality of the sample received into the converter which may include, preferably setting up a system to compare the amplitudes between signal samples. In present terms, the wrapped signals are received in 210 and the difference evaluated 220 between samples. With samples having large positive differences between samples over an accommodatable range 230, the system of the present invention preferably subtracts according to the range of difference and the accommodatable range from the evaluated sample 250, thus extending the range of the duly converted signal 270.

In instances, wherein the difference between samples presents a large negative difference outside an accommodatable range 240, the system of the present invention preferably adds according to the range of difference and the accommodatable range of the evaluated sample 260, thus extending the range of such duly converted signal 270. As a process of maintaining the quality of the input signal, if the difference between samples is neither larger positively nor negatively as evaluated within the accommodatable range, such signal may not be subject to any range extension according to the present invention. In instance, wherein the signal is unwrapped 270, said signal may then be output to file with the increased bit depth.

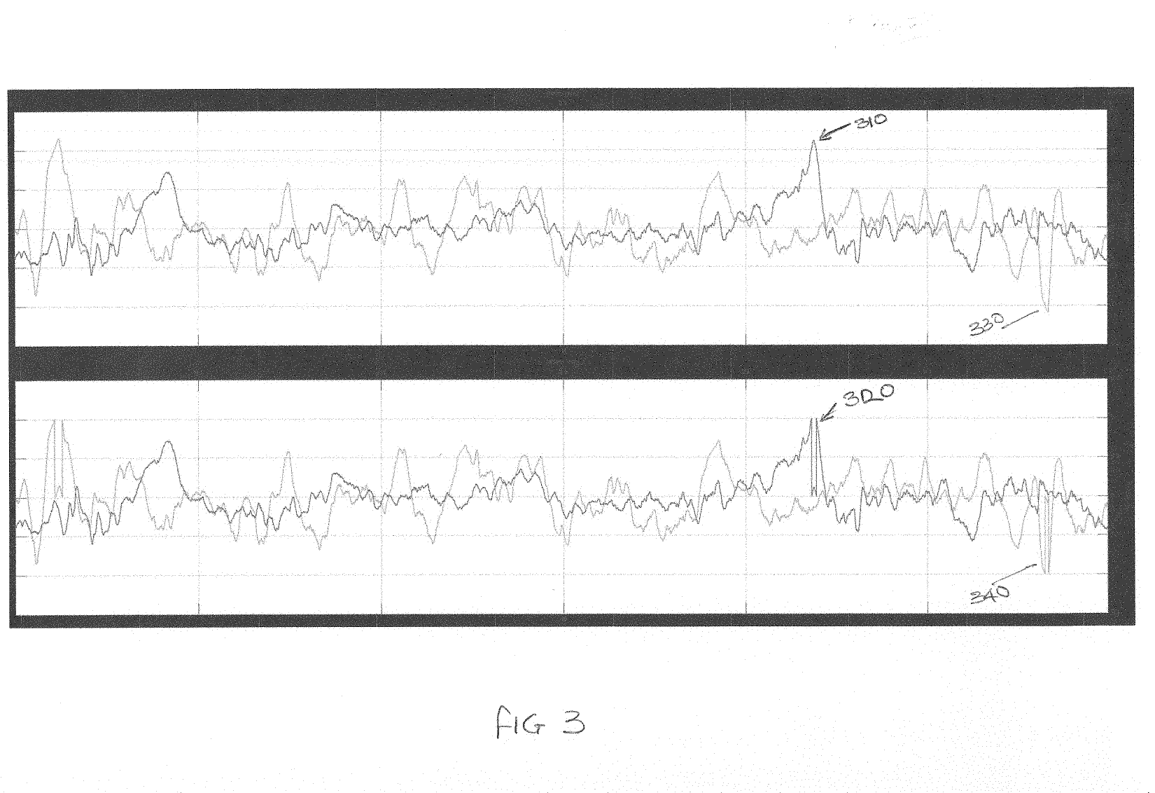

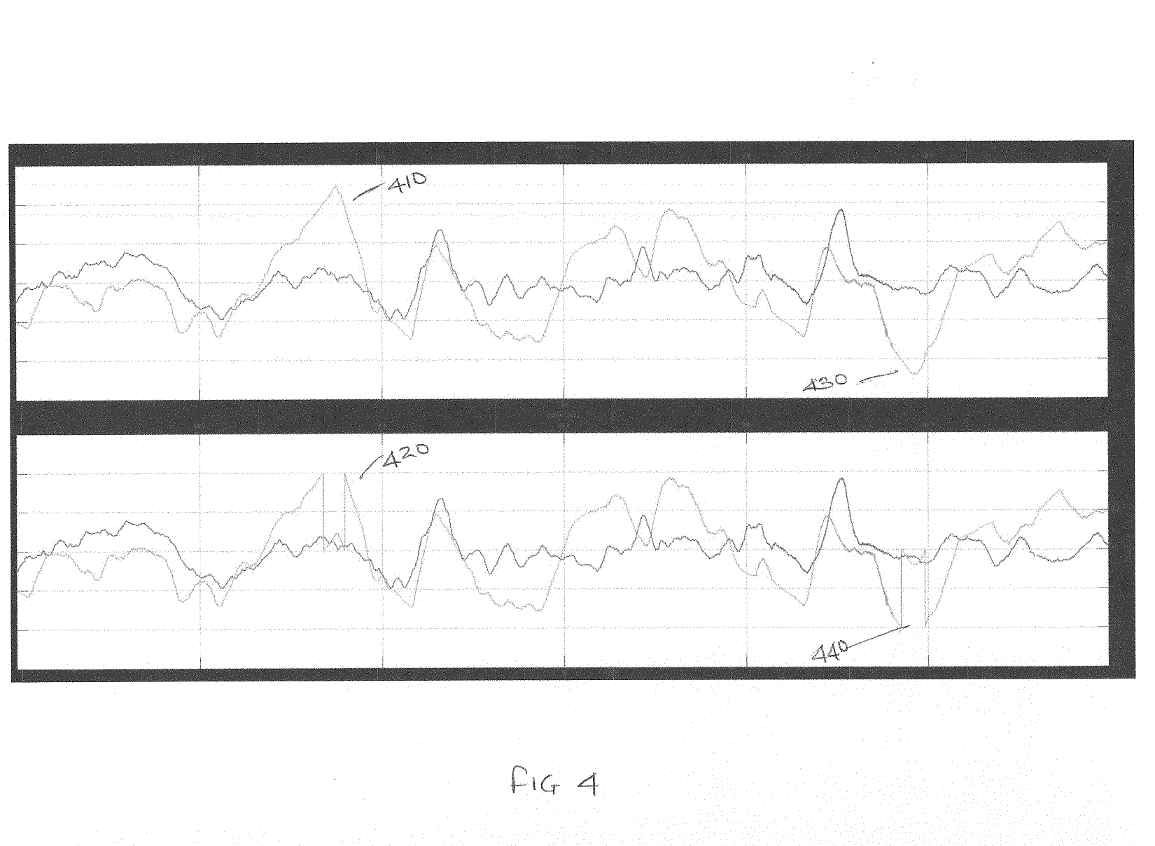

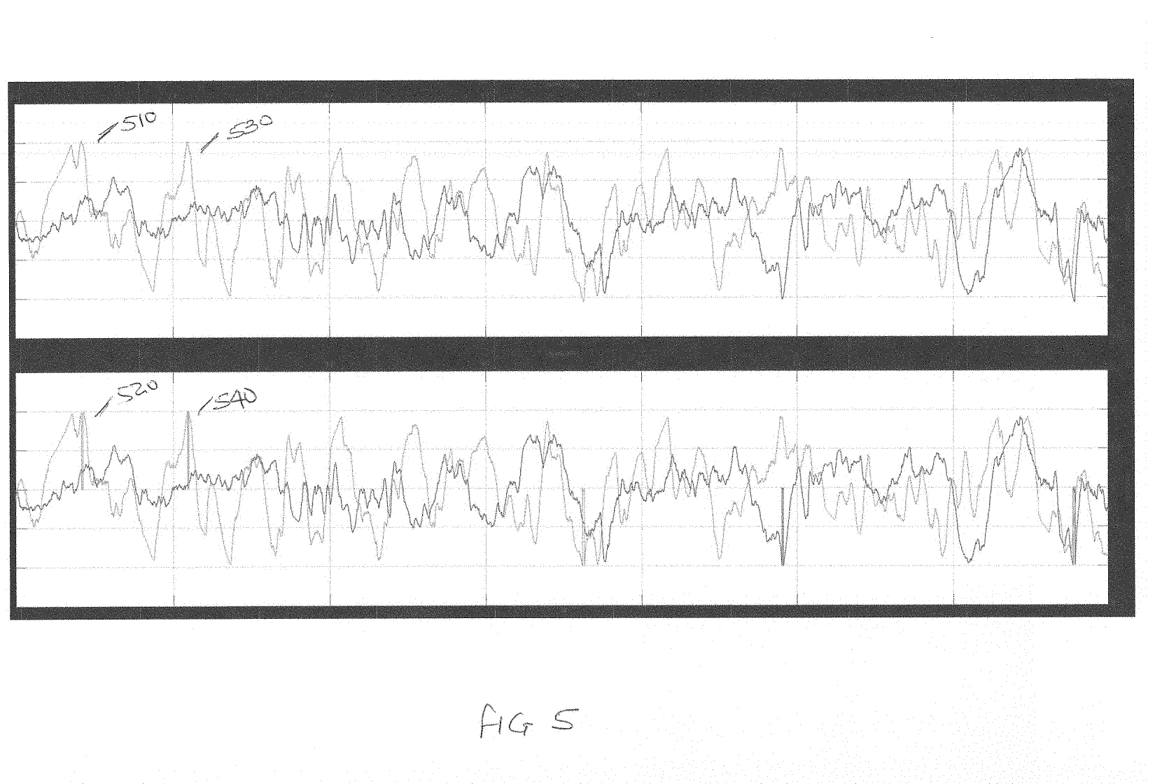

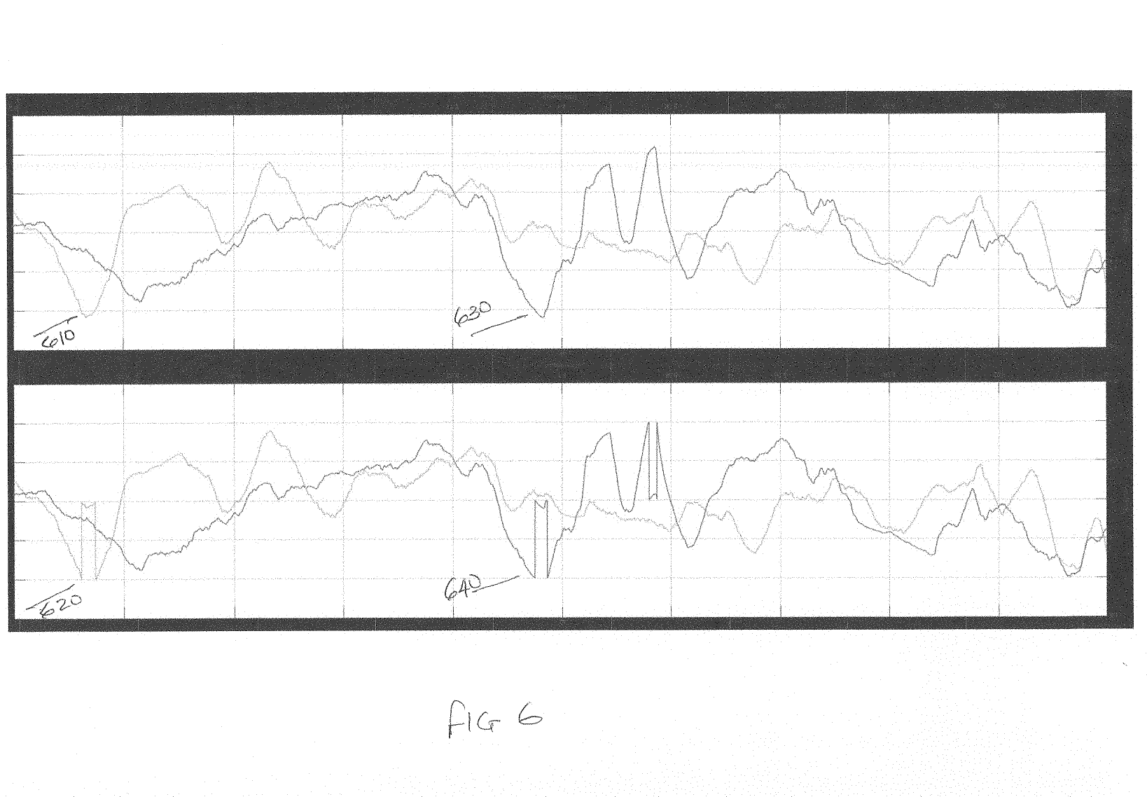

The present invention discloses a method and system for extending the dynamic range of analog to digital conversions. The process involves wrapping the signal, locating points of wrapping, and reconstructing the signal. This allows for an increased effective number of bits (ENOB), resulting in more information retained, or practically reconstructed by retaining and restoring the wrapped samples. The process preferably utilizes a modified phase-unwrapping algorithm without clipping the signal but wrapping for a cleaner and retained signal without the distortion as may be obtained with clipping. As indicated in the graphical displays of the FIGS. 3-6, wherein the display indicates in 310, 330, 410, 430, 510, 530, 610 and 630, the positively or negatively larger difference suitable to be wrapped and the commensurate 320, 340, 420, 440, 520, 540, 620 and 640 wrapped differences in signals according to the present invention. The present invention may preferably convert an analog, non-discontinuous signal to digital while avoiding clipping. The present invention provides a method of extending the dynamic range of analog to digital conversion whereby the conversion retains the signal and can then scale, as the user requires.

Signals as used in the present invention includes audio recordings as well as other non-discontinuous functions and signals. The system of the present invention recognizes points in the signal where wrapping occurs as said large or negative differences in signal comparison are wrapped at point of high or low amplitude. According to the present invention, upon recognition of the wrapping, the system, via a modified phase unwrapping algorithm, addresses the wrapping by “unwrapping” the signal, thereby retaining information that would normally be lost through saturation (clipped). The present invention provides the extension of the dynamic range of, and/or an increase of resolution in, the analog to digital conversion.

In addition to capturing non-discontinuous functions and signals, the present invention may also be used for transportation and storage of functions and signals. The new graphic as shown in the figures displays the converted signal without the distortion or defect. The user listening to the converted signal does not hear the audio with the popping at the location of the distortion.

While the disclosure has been, described with reference to exemplary embodiments, it will be understood by those skilled in the art that various changes may be made and equivalents may be substituted for elements thereof without departing from the scope of the disclosure. In addition, many modifications may be made to adapt a particular situation, material, step of component to the teachings without departing from the essential scope thereof. Therefore, it is intended that the disclosed subject matter not be limited to the particular embodiment disclosed as the best mode contemplated for carrying out this invention, but only by the claims that follow.

Having thus described the preferred embodiments of the present invention, those of skill in the art will readily appreciate that the teachings found herein may be applied to yet other embodiments.

What is claimed is:

1. A method of extending the dynamic range of analog to digital converters, comprising:
inputting a signal
convening said signal to voltage
converting the signal from analog to digital while wrapping the digital signal, and
evaluating the signal for large differences between samples, wherein said differences are unwrapped to produce signals with increased bit depth and extending the signal dynamic range without clipping.

2. The method of claim 1, wherein the differences between samples are reduced.
